(19) United States
(12) Patent Application Publication
(10) Pub. No.: US 2025/0308604 A1
(43) Pub. Date: Oct. 2, 2025

(54) OPERATING METHOD FOR CONTROLLING MEMORY CELL AND MEMORY SYSTEM

(71) Applicant: Winbond Electronics Corp., Taichung City (TW)

(72) Inventors: Chuen-Der Lien, Los Altos Hills, CA (US); Chi-Shun Lin, Fremont, CA (US)

(73) Assignee: Winbond Electronics Corp., Taichung City (TW)

(21) Appl. No.: 18/624,032

(22) Filed: Apr. 1, 2024

(51) Int. Cl. G11C 16/34; G11C 16/10; G11C 16/16; G11C 16/26

(52) U.S. Cl. CPC G11C 16/3459; G11C 16/102; G11C 16/16; G11C 16/26

(57) ABSTRACT

An operating method for controlling memory cell and a memory system are provided. The operating method is for controlling memory cells. The operating method comprises performing a first read operation to memory cells in a first area according to a first verification voltage to obtain a first verification result; and performing an erase operation to the memory cells in the first area, and a strength of the erase operation being determined according to the first verification result.

### BACKGROUND

### 1. Technical Field

The disclosure generally relates to a method and a system, in particular, to an operating method for controlling a memory cell and a memory system.

### 2. Description of Related Art

Regarding a flash memory, its memory function is usually implemented by altering a threshold voltage of a memory cell to a predetermined level through performing a program operation or erase operations on it according to an input data. However, the memory function of memory cell ages as a number of the program and erase operations performed on the memory cell increases, since the stress applied to the memory cell through the program and erase operations performed will be accumulated, and eventually causing the memory cell to fail.

### SUMMARY

Accordingly, the disclosure is directed to an operating method for controlling a memory cell and a memory system for minimizing the stress applied to the memory cell through the program and erase operations.

The operating method of the present disclosure is for controlling a memory cell, and the operating method comprises performing a first read operation to the memory cell according to a first verification voltage to obtain a first verification result; performing a second read operation to the memory cell according to a second verification voltage less than the first verification voltage to obtain a second verification result; and performing a program operation to the memory according to the first and second verification results, and a strength of the program operation being determined according to the second verification result.

The operating method of the present disclosure is for controlling memory cells, and the operating method comprises performing a first read operation to memory cells in a first area according to a first verification voltage to obtain a first verification result; and performing an erase operation to the memory cells in the first area, and a strength of the erase operation being determined according to the first verification result.

The memory system of the present disclosure includes a memory array, a controller, and a program circuit. The memory array comprises a memory cell. The controller is coupled to the memory array and is configured to perform a first read operation to the memory cell according to a first verification voltage to obtain a first verification result; and to perform a second read operation to the memory cell according to a second verification voltage less than the first verification voltage to obtain a second verification result; and to perform a program operation to the memory, and a program strength of the program operation being determined according to the second verification result. The program circuit is coupled to the controller and configured to provide a program signal at a first strength or a second strength greater than the first strength to the memory cell according to the first and second verification results.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1, 3A, 3C, 3E and 3G are flow charts of an operating method for controlling a memory cell according to some embodiments of the present disclosure.

FIG. 2A illustrates a process of how the threshold voltage of the memory cell is changed during the process of the operating method of FIG. 1.

FIG. 2B illustrates how the threshold voltage of the memory cell is changed during a preprogram process according to some embodiments of the present disclosure.

FIGS. 3B and 3D illustrates distribution curves according to some embodiments of the present disclosure.

FIGS. 3F and 3H illustrates verification voltages and a distribution curve according to some embodiments of the present disclosure.

FIG. 4A is a schematic diagram of a memory system according to some embodiments of the present disclosure.

FIG. 4B illustrates a logic circuit according to some embodiments of the present disclosure.

### DESCRIPTION OF THE EMBODIMENTS

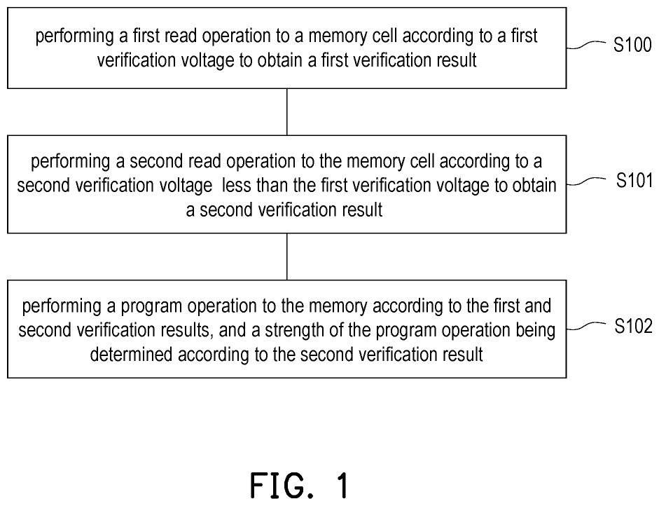

FIG. 1 is flow chart of an operating method for controlling a memory cell according to some embodiments of the present disclosure. The operating method may be utilized for programming the memory cell. The memory cell may be for example a NOR flash memory cell where its threshold voltage may be programmed at different levels based on the data value to be written in. In general, the operating method may assist process of the program operation, so the threshold voltage of the memory cell may be set at an appropriate strength level to further reduce stress of the memory cell and thereby improving its endurance.

The operating method includes steps S100-S102. In step S100, a first read operation is performed to a memory cell according to a first verification voltage to obtain a first verification result. More specifically, during the first read operation, information about the threshold voltage of the memory cell may be readout such that the threshold voltage may be compared with the first threshold voltage. The first verification voltage may be used for determining a data value stored by the memory cell to determine a data information (i.e., the first verification result) corresponding to the memory cell accordingly. In some embodiments, when the threshold voltage of the memory cell is greater than or equal to the first verification voltage, the data information corresponding to the memory cell is set to a first value (e.g., bit value 1). When the threshold voltage of the memory cell is less than the first verification voltage, the data information corresponding to the memory cell is set to a second value (e.g., bit value 0).

In step S101, a second read operation is performed to the memory cell according to a second verification voltage to obtain a second verification result, wherein the second verification voltage is less than the first verification voltage. More specifically, the second verification voltage may be located at a preset voltage level corresponding to where the bit value 0 should be programmed. Ideally, the threshold voltage of the memory cell storing the digital value 0 should be at the preset voltage level, but, however, the threshold voltage of the memory cell storing the digital value 0 may be deviated from the preset voltage level corresponding to the bit value 0 due to process variations or other nonidealities. Therefore, the second read operation may be used for determining a location information (e.g., the second verification result) on where the threshold voltage of the memory cell is deviated from the preset voltage level corresponding to the digital value 0. For example, the second verification result generated from the second read operation may contain information related to which side of the preset voltage level the threshold voltage of the memory cell is located on, or how far a distance between the threshold voltage of the memory cell and the preset voltage level is. In some embodiments, when the threshold voltage of the memory cell is greater than or equal to the second verification voltage, the second verification result of the memory cell is set to the first value (e.g., bit value 1). When the threshold voltage of the memory cell is less than the first verification voltage, the second verification result of the memory cell is set to the second value (e.g., bit value 0).

In step S102, a program operation is performed to the memory according to the first and second verification results, and a strength of the program operation is determined according to the second verification result. More specifically, during the program operation, a program signal is applied to the memory cell for shifting the threshold voltage of memory cell to a voltage level corresponding to the digital value 1. For example, the strength of the program operation is controlled by at least one of a program voltage and a program time of the program signal. As such, for the memory cell whose threshold voltage is already greater than or equal to the first verification voltage (i.e., the data information is set to 1), there is no necessity to perform the program operation to the memory cell since it already stores the digital value 1. On the other hand, for the memory cell whose threshold voltage is less than the first verification voltage (i.e., the data information is set to 0), the program operation will be performed. The program operation may be performed for one time or multiple times to right-shift the threshold voltage until the threshold voltage greater than or equal to the first verification voltage. Further, before the program operation is performed, the second verification result may be taken into consideration for adjusting the strength of the program operation. In other words, the strength of the program operation may be set based on the location information between the threshold voltage of the memory cell and the preset voltage level. When the threshold voltage of the memory cell is greater than or equal to the second verification voltage, the strength of the program operation is set to a first strength. When the threshold voltage of the memory cell is less than the second verification voltage, the strength of the program operation is set to a second strength greater than the first strength. In other words, when the threshold voltage of the memory cell is closer to the first verification voltage, the program operation may be set to a weaker strength to reduce stress applied to the memory cell during the program operation.

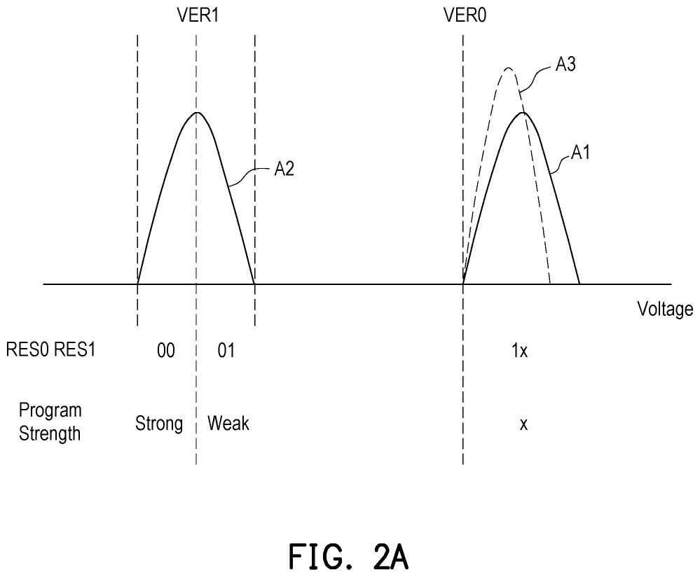

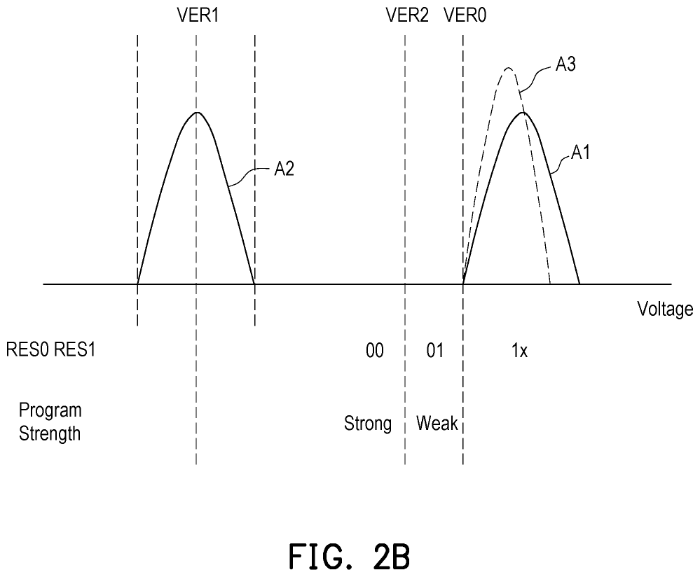

FIG. 2A illustrates a process of how the threshold voltage of the memory cell is changed during the process of the operating method of FIG. 1. In FIG. 2A, distribution curves A1 and A2 respectively correspond to probability distribution curves of the threshold voltage of the memory cell respectively storing the digital values 1 and 0 before the program operation in FIG. 1 is performed, and a distribution curve A3 corresponds to a probability curve of the threshold voltage of the memory cell after the program operation is performed.

Referring to FIG. 1, in step S100, a verification voltage VER0 is used in the first read operation for distinguishing whether the memory cell stores the digital value 0 or 1. When the threshold voltage of the memory cell is greater than or equal to the verification voltage VER0, a verification result RES0 showing that the memory cell stores the digital value 1 is generated. Otherwise, when the threshold voltage of the memory cell is less than the verification voltage VER0, the verification result RES0 showing that the memory cell stores the digital value 0 is generated.

In step S101, a verification voltage VER1 is used in the second read operation for evaluating on which side of the preset voltage level the threshold voltage of the memory cell is. More particularly, the verification voltage VER1 is set at the preset voltage level where the threshold voltage corresponding to the digital value 0 should be programmed which is usually at a center of the distribution curve A2 if the distribution is a normal distribution or other probabilistic models having a symmetrical distribution curve. As such, when the threshold voltage of the memory cell is greater than or equal to the verification voltage VER1, it may be determined that the threshold voltage of the memory cell is located on right side of the verification voltage VER1, and a verification result RES1 set to the digital value 1 can be generated. Otherwise, when the threshold voltage of the memory cell is less than the verification voltage VER1, it may be determined that the threshold voltage of the memory cell is located on left side of the verification voltage VER1, and the verification result RES1 set to the digital value 0 can be generated.

In step S102, based on the generated verification results RES0 and RES1, whether the program operation is performed and how strong the program operation is performed may be determined. More particularly, whether the program operation is performed on the memory cell may be evaluated according to the verification result RES0. Once it is verified that the memory cell stores the digital value 0 according to the verification result RES0, the program operation may be determined to be performed on the memory cell and the strength of the program operation determined according to the verification result RES1.

More particularly, the program operation may be performed on the memory cell when the verification result RES0 is 1. Otherwise, when the verification result RES0 is 0, it may be determined that the memory cell is storing the digital value 0 and the program operation may be performed on the memory cell accordingly. Therefore, when the verification results RES0, RES1 are 01, it can be seen in FIG. 2A that the corresponding threshold voltage of the memory cell is in between of the verification voltages VER0, VER1 and closer to the verification voltage VER0, and thus the strength of the program operation may be set to the first strength which is weaker. On the other hand, when the verification results RES0, RES1 are 00, it can be seen in FIG. 2A that the corresponding threshold voltage of the memory cell is farther from the verification voltage VER0, so the strength of the program operation is set to the stronger second strength. Consequently, the probability curve of the threshold voltage of the memory cell after the program operation is performed may be shown as the distribution curve A3 which has a shape of more concentrated distribution with higher peak compared with the distribution curve A1. In other words, it is demonstrated by the distribution curve A3 that lower stress is applied to the memory cell during the process of the program operation, thereby improving endurance of the memory cell.

Although the steps S100 and S101 are depicted in FIG. 2A as separate steps with the step S100 performed before the step S101, however, there are no certain sequences or formations for the steps S100, S101 as long as the threshold voltage of the memory cell may be compared with the multiple verification voltages VER0, VER1. The two steps may be performed separately with an arbitrary order or the two steps may also be integrated as a single step. For example, the step S101 may be performed before the step S100, or the two steps S100, S101 may be performed simultaneously. When the steps S100, S101 are performed simultaneously, the threshold voltage of the memory cell may be compared with both of the verification voltages VER0, VER1 at the same time through, for example, a multi-level comparator or an analog-to-digital converter (ADC) to obtain the first and second verification results RES0, RES1. In some embodiments, the first and second read operations may be combined and regarded as a multi-level read operation which is capable of comparing the threshold voltage of the memory cell with multiple verification voltages.

Further, although in FIGS. 1, 2A, the multi-level read operation is applied according to the verification voltages VER0, VER1, however, there can be more than two verification voltages or the comparison can be performed more than twice. For example, there may be more verification voltages set for dividing the distribution curve A2 in FIG. 2A with smaller spacings rather than the verification voltage VER1 located at the center of the threshold voltage VER, so the verification result VER1 may be obtained for indicating the location information with a finer resolution on how far the threshold voltage of the memory cell is ranging from the preset voltage level corresponding to the digital value 0.

FIG. 2B illustrates how the threshold voltage of the memory cell is changed during a preprogram process according to some embodiments of the present disclosure. In some embodiments, after the program operation is performed on the memory cell, the preprogram operation may be selectively performed on the memory cell if the threshold voltage of the memory cell has not exceeded the verification result VER0.

In some circumstances, after the program operation, there is still a slight probability that the threshold voltage of the memory cell has not exceeded the verification voltage VER0 which means that the digital value 1 has not been stored by the memory cell, and it is required for the preprogram operation to be performed on the memory cell. In order to evaluate the necessity for the preprogram operation, the multi-level read operation similar to the steps S100, S101 depicted in FIGS. 1 and 2A may be performed on the memory cell again except that the verification voltage VER1 in FIG. 2A is adjusted to a higher verification voltage VER2 depicted in FIG. 2B during the preprogram operation.

More particularly, the multi-level read operation includes performing the read operations on the memory cell according to the verification voltages VER0, VER2. The first read operation performed according to the verification voltage VER0 is for verifying whether the digital value 0 or 1 is stored by the memory cell and to generate the verification result RES0 accordingly. Once it is verified that the threshold voltage of the memory cell is greater than or equal to the verification voltage VER0, there will be no necessity for the preprogram operation to be performed on the memory cell since the memory cell is verified to be programmed successfully. Otherwise, when the threshold voltage is less than the verification voltage VER0, the preprogram operation will be performed to the memory cell to help the threshold voltage to be right-shifted to be greater than the verification voltage VER0.

In order to determine a strength of the preprogram operation adapted to the threshold voltage of the memory cell, the read operation according to the verification voltage VER2 may be performed on the memory cell. The verification voltage VER2 is set at a level between the verification voltages VER0, VER1 and closer to the verification voltage VER0. For example, the verification voltage VER2 may be set 0.2 V less than the verification voltage VER0. When the read operation according to the verification voltage VER2 is performed on the memory cell, a location information on how far a distance between the threshold voltage of the memory cell between the verification voltage VER0 may be obtained. Therefore, the strength of the preprogram operation may be performed according to the location information. More particularly, when the threshold voltage of the memory cell is greater than or equal to the verification voltage VER2, the strength of the preprogram operation is set to a weaker third strength. When the threshold voltage of the memory cell is less than the verification voltage VER2, the strength of the preprogram operation is set to a fourth strength stronger than the third strength. In other words, the multi-level read operation may be performed after the program operation for assessing the program operation, so the necessity and the strength of the preprogram operation may be accordingly evaluated.

In some embodiments, after the preprogram operation is performed, the multi-level read operation may be repeated to further evaluate whether the digital value 1 has been programmed to the memory cell or not. For example, the preprogram operation and the multi-level read operation with the same verification voltage VER2 or different verification voltages may be repeated for a predetermined number of times.

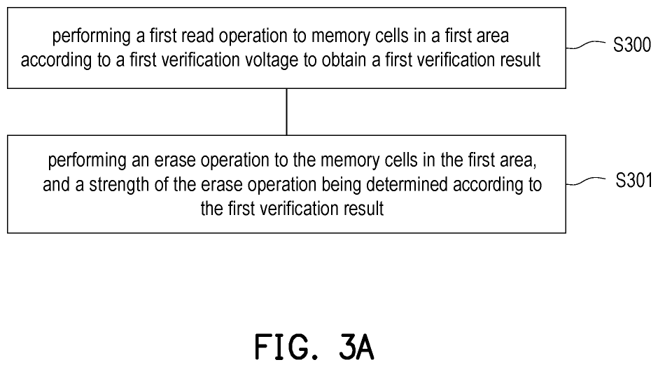

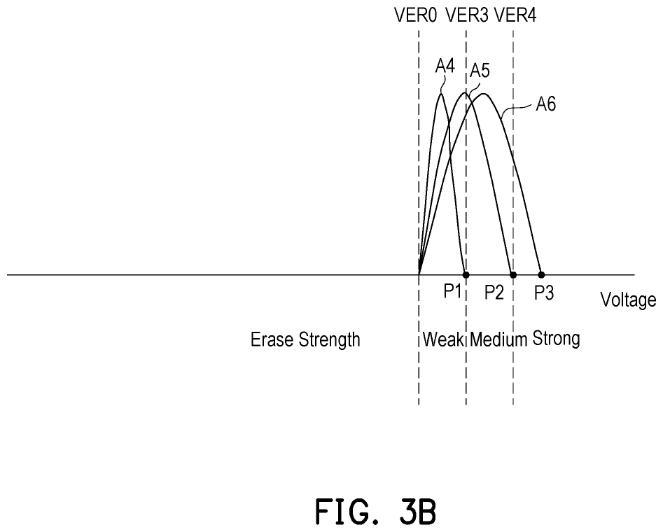

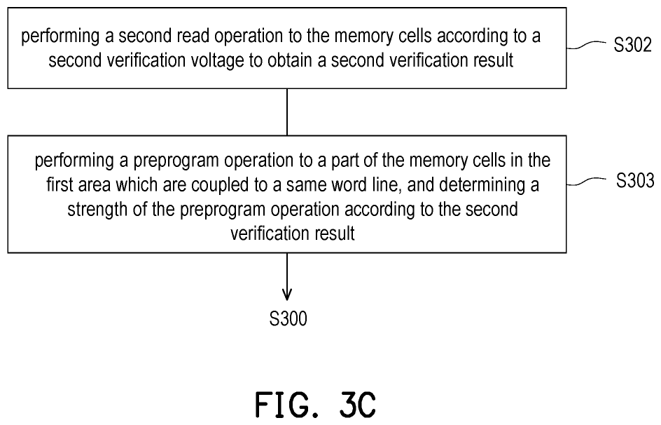

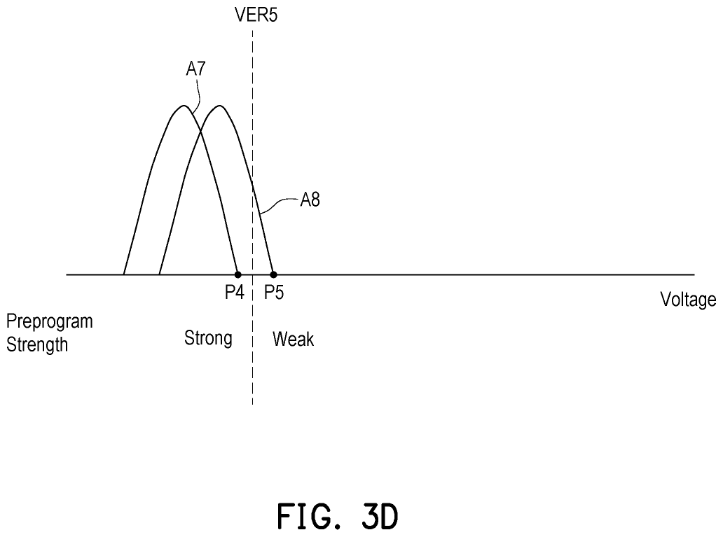

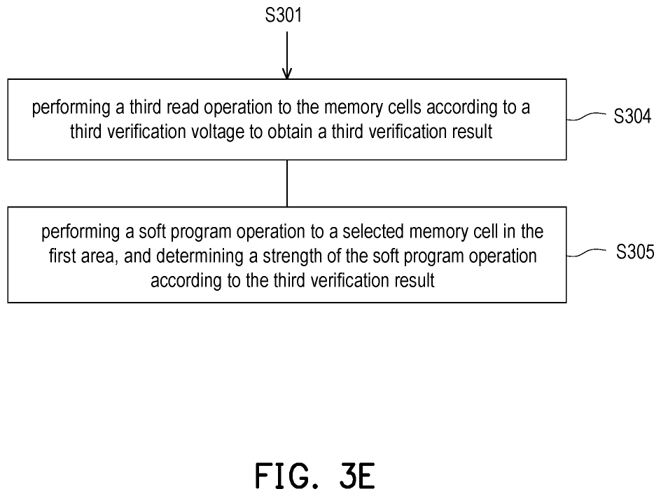

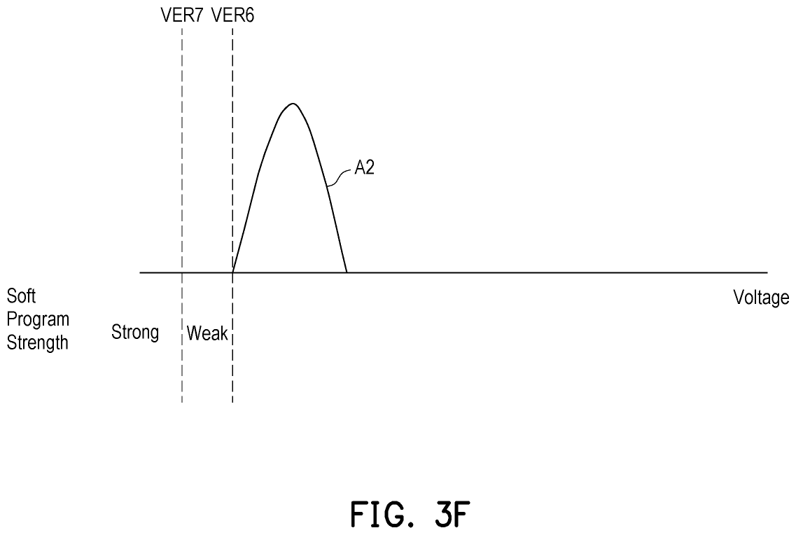

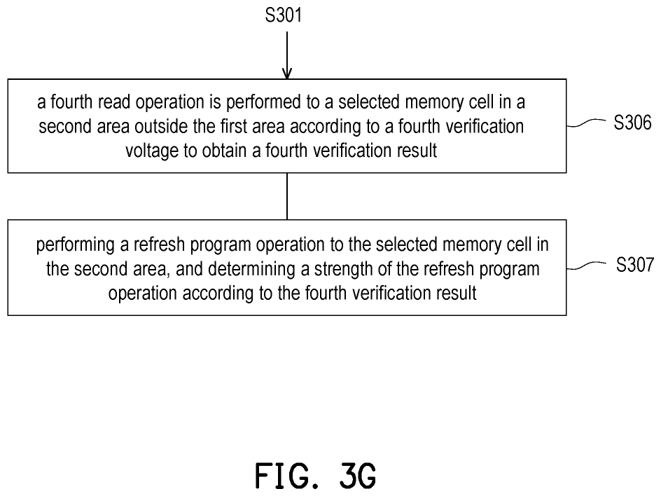

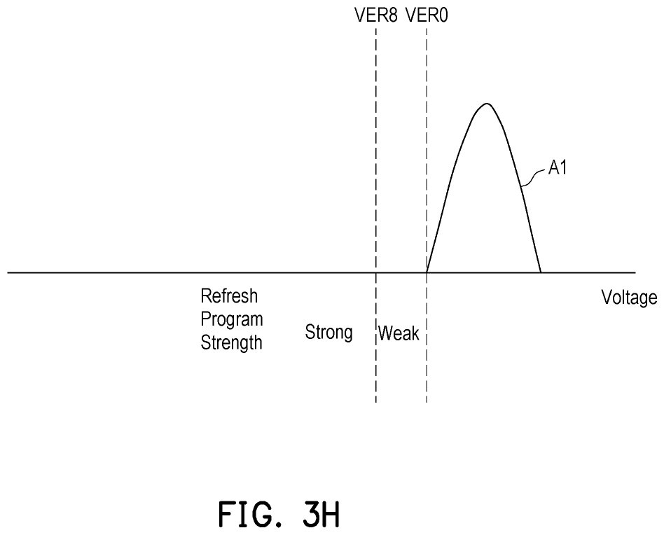

FIG. 3A is a flow chart of an operating method for controlling a memory cell according to some embodiments of the present disclosure. The operating method may be used for performing an erase operation to memory cells in a certain area. Generally speaking, the erase operation is performed to all memory cells in such area, and the operating method in FIG. 3A may assist the strength of the erase operation to be set at an appropriate strength to reduce stress applied to the memory cell and thereby improving its endurance.

The operating method includes steps S300, S301. In step S300, a first read operation is performed to memory cells in a first area according to a first verification voltage to obtain a first verification result. More particularly, during the first read operation, all threshold voltages of the memory cells in the same area are compared with the first verification voltage to generate the first verification result which indicates whether all threshold voltages of the memory cells in this first area are less than the first verification voltage.

In step S301, the erase operation is performed to the memory cells in the first area, and a strength of the erase operation is determined according to the first verification result. More particularly, when the largest threshold voltage of the memory cells in the first area is greater than or equal to the first verification voltage, the strength of the erase operation is set to a first strength. When the largest threshold voltage of the memory cells in the first area is less than the first verification voltage, the strength of the erase operation is set to a second strength less than the first strength.

FIG. 3B illustrates distribution curves A4-A6 according to some embodiments of the present disclosure. The distribution curve A4-A6 respectively represent different probability distribution curves of the threshold voltages of the memory cells in a same area. In some embodiments, the first read operation may include multiple verification voltages, so the generated verification result may indicate whether all threshold voltages of the memory cells are below those verification voltages. In another aspect, the first read operation is to compare the largest threshold voltage (i.e., the right most point) on the distribution curve with each verification voltage to generate the verification result, so the verification result includes comparison results regarding the largest threshold voltage with each of the verification voltages, and the strength of the following erase operation may be adjusted accordingly. For example, for the distribution curve A4 with a largest threshold voltage point P1 being less than the verification voltage VER3, the strength of the erase operation performed to the memory cells having the distribution curve A4 is set to a strength at a relatively weak level. Further, for the distribution curve A5 with a largest threshold voltage point P2 being less than the verification voltage VER4, the strength of the erase operation performed to the memory cells having the distribution curve A5 is set to a strength at a medium level. For the distribution curve A6 with a largest threshold voltage point P3 being greater than the verification voltage VER4, the strength of the erase operation performed to the memory cells having the distribution curve A5 is set to a strength at a strength level relatively strong.

FIG. 3C is a flow chart of an operating method for controlling a memory cell according to some embodiments of the present disclosure. The operating method may be used for performing a preprogram operation to the memory cells coupled to a same word line before the erase operation. Since an objective of the erase operation is to shift the threshold voltages of all memory cells in the first area from corresponding to the digital value 1 to corresponding to the digital value 0, it is required to perform the preprogram operation selectively to the memory cell of storing the digital value 0 such that all memory cells in the first area are set at the programmed state.

Before performing the preprogram operation, the memory cells in the first area storing the digital value 0 may be selected through, for example, the step S100 as discussed in above paragraphs in relation to FIG. 1. Then, the memory cells storing the digital value 0 may be selected for the preprogram operation to be performed to.

In step S302, a second read operation is performed to the memory cells according to a second verification voltage to obtain a second verification result. More particularly, during the second read operation, each threshold voltage of the selected memory cells is compared with the second voltage to generate a second verification result indicating whether each threshold voltage is greater than or equal to the second verification voltage.

In step S303, a preprogram operation is performed to at least one selected memory cell coupled to a same word line in the first area, and a strength of the preprogram operation is determined according to the second verification result. More particularly, the preprogram operation will be and the multi-level read operation performed repeatedly until all memory cells coupled to the same word line are set at the programmed state. Further, the strength of the preprogram operation is determined by the largest threshold voltage of the selected memory cells on each word line. When the largest threshold voltage of the at least one selected memory cell coupled to the same word line in the first area is greater than or equal to the second verification voltage, the strength of the preprogram operation is set to a third strength. When the largest threshold voltages of the at least one selected memory cell coupled to the same word line in the first area is less than the second verification voltage, the strength of the preprogram operation is set to a fourth strength greater than the third strength.

FIG. 3D illustrates distribution curves A7, A8 according to some embodiments of the present disclosure. The distribution curves A7, A8 represent threshold voltage distributions of the memory cells storing the digital value 0 on a same word line. The second read operation compares the largest threshold voltage point of the distribution curve with each verification voltage to generate the verification result, so the strength of the preprogram operation may be accordingly adjusted. For example, for the distribution curve A7 with a largest threshold voltage point P4 being less than the verification voltage VER5, the strength of the preprogram operation performed to the memory cells corresponding to the distribution curve A4 on the same word line is set to a fourth strength. Further, for the distribution curve A8 with a largest threshold voltage point P5 being greater than the verification voltage VER5, the strength of the preprogram operation performed to the memory cells corresponding to the distribution curve A8 is set to the third strength weaker than the fourth strength.

FIG. 3E is a flow chart of an operating method for controlling a memory cell according to some embodiments of the present disclosure. The operating method may be executed after the erase operation for performing a soft program operation to a selected memory cell in the first area. Generally speaking, after performing the erase operation, there might be a certain probability that the threshold voltage of the memory cell is still too low which requires to be right-shifted. Therefore, the soft operation may be performed to those memory cells whose threshold voltages are too low so the threshold voltages of all memory cells in the first area are controlled to be to the preset voltage level corresponding to the digital value 0 as depicted in FIGS. 2A, 2B.

After performing the erase operation, the memory cells in the first area with the threshold voltages being less than a least tolerable voltage corresponding to the digital value 0 may be selected. Then, the soft operation may be performed on those selected memory cells with the threshold voltages being too low.

In step S304, a third read operation is performed to the selected memory cell according to a third verification voltage to obtain a third verification result. More particularly, during the third read operation, the threshold voltage of the selected memory cell is compared with the third verification voltage to generate a third verification result indicating whether the threshold voltage is greater than or equal to the third verification voltage.

In step S303, a soft program operation is performed to the selected memory cell in the first area, and a strength of the soft program operation according to the third verification result. In some embodiments, the soft program operation is performed repeatedly until all threshold voltages of all memory cells in the first area are greater than the a least tolerable voltage corresponding to the digital value 0. More particularly, when the threshold voltage of the selected memory cell is greater than or equal to the third verification voltage, the strength of the soft program operation is set to a fifth strength. When the threshold voltage of the selected memory cell is less than the third verification voltage, the strength of the soft program operation is set to a sixth strength greater than the fifth strength.

FIG. 3F illustrates verification voltages VER6, VER7 and a distribution curve A2 according to some embodiments of the present disclosure. The distribution curves A2 represent a threshold voltage distribution of the memory cells storing the digital value 0 as described in relation to FIG. 2A. The verification voltage VER6 is the least tolerable voltage corresponding to the digital value 0, and the verification voltage VER7 is the third verification voltage.

Before performing the soft operation, threshold voltages of all memory cells may be compared with the verification voltage VER6 to find out those memory cells with the threshold voltages being too low. More particularly, the verification voltage VER6 is set at a voltage level less than all threshold voltages of the distribution curve A2. Then, the soft operation may be performed on those selected memory cells with the threshold voltages being lower than the verification voltage VER6. The third read operation compares the threshold voltage of each selected memory cell to the verification voltage VER7 to generate the verification result, so the strength of the soft program operation may be accordingly adjusted. For example, for the memory cell having the threshold voltage being greater than or equal to the verification voltage VER7, the strength of the soft program operation is set to the fifth strength. Further, for the memory cell having the threshold voltage being less than the verification voltage VER7, the strength of the soft program operation is set to the sixth strength greater than the sixth strength.

FIG. 3G is a flow chart of an operating method for controlling a memory cell according to some embodiments of the present disclosure. The operating method may be executed after the erase operation, for performing a refresh program operation the memory cells storing the digital value 1 outside the first area. Specifically, the erase operation might affect other memory cells outside the first area, so after the erase operation, the refresh program operation may be performed to the memory cells storing the digital value in the second area outside the first area.

In step S306, a fourth read operation is performed to a selected memory cell in a second area outside the first area according to a fourth verification voltage to obtain a fourth verification result. More particularly, during the fourth read operation, the threshold voltage of the selected memory cell is compared with the fourth verification voltage to generate the fourth verification result indicating whether the threshold voltage is greater than or equal to the fourth verification voltage.

In step S307, a refresh program operation is performed to the selected memory cell in the second area, and determining a strength of the refresh program operation according to the fourth verification result. More particularly, when the threshold voltage of the selected memory cell is greater than or equal to the fourth verification voltage, the strength of the refresh program operation is set to a seventh strength. When the threshold voltage of the selected memory cell in the second area is less than the fourth verification voltage, the refresh program operation is set to an eighth strength greater than the seventh strength.

FIG. 3H illustrates verification voltages VER0, VER8 and a distribution curve A1 according to some embodiments of the present disclosure. The distribution curves A1 represent a threshold voltage distribution of the memory cells storing the digital value 1 as described in relation to FIG. 2A. The verification voltage VER0 is the least tolerable voltage corresponding to the digital value 0, and the verification voltage VER8 is the fourth verification voltage.

After performing the erase operation, threshold voltages of all memory cells in the second area may be compared with the verification voltage VER0 to find out those memory cells with the threshold voltages being too low. As described in paragraphs in relation to FIG. 2A, the verification voltage VER0 is used for distinguishing the threshold voltages corresponding to the digital value 0 and 1, so the verification voltage VER0 is set at a least tolerable voltage corresponding to the digital value 1, which is less than all threshold voltages in the distribution curve A1. Then, the soft operation may be performed on those selected memory cells in the second area with the threshold voltages being lower than the verification voltage VER0. The fourth read operation compares the threshold voltage of each selected memory cell to the verification voltage VER8 to generate the verification result, so the strength of the refresh program operation may be accordingly adjusted. For example, for the memory cell having the threshold voltage being greater than or equal to the verification voltage VER8, the strength of the refresh program operation is set to the seventh strength. Further, for the memory cell having the threshold voltage being less than the verification voltage VER8, the strength of the refresh program operation is set to the eighth strength greater than the seventh strength.

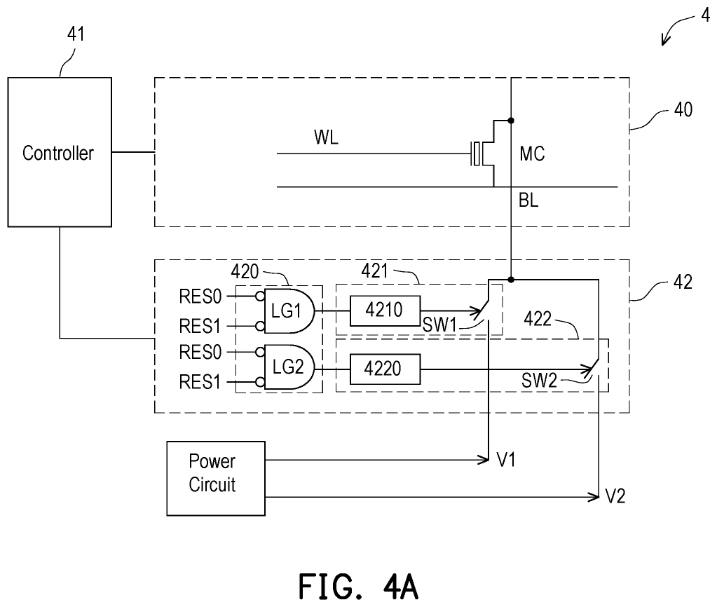

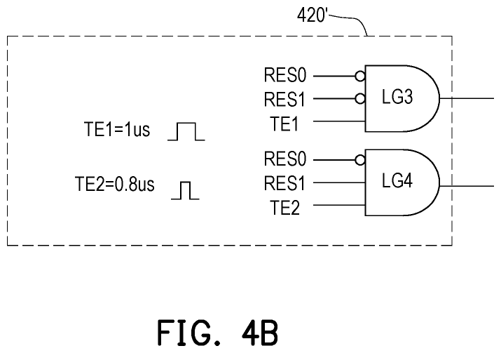

FIG. 4A is a schematic diagram of a memory system 4 according to some embodiments of the present disclosure. The memory system 4 includes a memory array 40, a controller 41, and a program circuit 42. The memory array 40 includes a plurality of memory cells arranged in rows and columns although there is only one memory cell MC is illustrated in FIG. 4A for simplicity. Each memory cell in the memory array 40 is coupled to between a bit line BL and a source line SL, and controlled by a word line WL. The controller 41 is coupled to the memory array 40 for controlling operations of the memory cell. More particularly, the controller 41 may be configured to perform the operating method in above paragraph and described in relation to FIGS. 1, 2A. The program circuit 42 is coupled to the controller 41, and configured to provide a program signal at a first strength or a second strength greater than the first strength to the memory cell MC according to the first and second verification results. Therefore, the controller 41 is configured to perform the first and second read operations to the memory cell to obtain the corresponding the first and second verification results. The generated first and second results may be provided to the program circuit 42, so the memory cell may be programmed by the program strength at an appropriate voltage level corresponding to the threshold voltage of itself.

Particularly, the program circuit 42 includes a logic circuit 420 and switch circuits 421, 422. The switch circuit 421 is configured to selectively provide a program signal V1 having the first strength to the memory cell MC through the bit line BL. The switch circuit 422 is configured to selectively provide a program signal V2 having the second strength to the memory cell MC through the bit line BL. The logic circuit 420 is coupled to receive the first and second verification results RES0, RES1, and configured to control operations of the switch circuits 421, 422, such that one of the program signals V1, V2 is provided to the memory cell through the bit line BL.

In some embodiments, the logic circuit 420 includes logic gates LG1, LG2. The logic gate LG1 is configured to generate an output signal at an enabled voltage level when the verification results RES0, RES1 are 00. On the other hand, the logic gate LG2 is configured to generate an output signal at an enabled voltage level when the verification results RES0, RES1 are 01. The output signals generated by the logic gates LG1, LG2 are respectively provided to high voltage switches 4210, 4220 of the switch circuits, for further controlling operations of the switches SW1, SW2. Therefore, when the first and second verification results RES0, RES1 indicate that the threshold voltage of the memory cell MC is between the verification voltages VER0 and VER1, the program signal V2 having the second strength is provided to the memory cell MC. When the first and second verification results RES0, RES1 indicate that the threshold voltage of the memory cell MC is less than the verification voltage VER1, the program signal V1 having the first strength is provided to the memory cell MC.

In some embodiments, the strength of the program operation is controlled by at least one of a program voltage and a program time of the program signal. For example, the program signal V1 may be at 4.2 V and the program signal V2 may be at 4 V, so the program signal V1 has higher strength than the program signal V2 owing to the higher voltage level. In another example, the program signals V1, V2 may be at the same voltage level, but different time lengths of enabled periods. Both of the program signals V1, V2 may be at 4V, but, however, the enabled period of the program signal V1 may have a longer time length of 1 microsecond which is longer than 0.8 microsecond of the enabled period of the program signal V2.

FIG. 4B illustrates a logic circuit 420′ according to some embodiments of the present disclosure. More particularly, the logic circuit 420′ may be applied to replace the logic circuit 420 in the memory system 4 as depicted in FIG. 4. The circuit architectures of the logic circuits 420, 420′ are similar, so the same components are represented by the same symbols.

The logic circuit 420′ includes logic gates LG3, LG4. The logic gates LG3, LG4 are respectively similar to the logic gates LG1, LG2, besides that the logic gate LG3 additionally receives an enabled signal TE1 and the logic gate LG4 additionally receives an enabled signal TE2. Time lengths of positive half cycle of the generated outputs of the logic gates LG3, LG4 are respectively controlled by the enabled signals TE1, TE2. In other words, the program signals V1, V2 are not only varied by their different voltage levels, but also different enabled periods they are enabled.

In some embodiments, each of the logic circuits 420, 420′ may be used while implementing the preprogram operation in FIG. 3C, or the soft program operation in FIG. 3E, or the refresh program operation in FIG. 3G for selectively providing the program signal at an appropriate strength.

In summary, the operating method and the memory system mentioned in the above may perform the multi-level read operation before the program/erase operation. The multi-level read operation may be used to obtain location information on where the threshold voltage of the memory cell is located, so a strength of the program/erase operation may be accordingly adjusted. As a result, less stress is applied to the memory cell during the program/erase operation and endurance of the memory system is improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An operating method for controlling a memory cell, the operating method comprising:
performing a first read operation to the memory cell according to a first verification voltage to obtain a first verification result;
performing a second read operation to the memory cell according to a second verification voltage less than the first verification voltage to obtain a second verification result;
performing a program operation to the memory according to the first and second verification results, and a strength of the program operation being determined according to the second verification result.

2. The operating method of claim 1, wherein when a threshold voltage of the memory cell is greater than or equal to the first verification voltage, a data information stored by the memory cell is set to a first value, and
when the threshold voltage of the memory cell is less than the first verification voltage, the data information stored by the memory cell is set to a second value.

3. The operating method of claim 2, wherein when the data information stored by the memory cell is the second value, it is set for the program operation to be performed on the memory cell.

4. The operating method of claim 1, wherein when a threshold voltage of the memory cell is greater than or equal to the second verification voltage, the strength of the program operation is set to a first strength, and
when the threshold voltage of the memory cell is less than the second verification voltage, the strength of the program operation is set to a second strength greater than the first strength.

5. The operating method of claim 1, wherein the strength of the program operation is controlled by at least one of a program voltage and a program time.

6. The operating method of claim 1, wherein after the program operation, a third read operation is performed to the memory cell according to a third verification voltage between the first and second verification voltages to obtain a third verification result,
a preprogram operation is performed to the memory cell according to the third verification result, and a strength of the preprogram operation is determined according to the third verification result.

7. The operating method of claim 6, wherein when the threshold voltage of the memory cell is greater than or equal to the third verification voltage, the strength of the preprogram operation is set to a third strength, and
when the threshold voltage of the memory cell is less than the third verification voltage, the strength of the preprogram operation is set to a fourth strength greater than the third strength.

8. An operating method for controlling memory cells, the operating method comprising:
performing a first read operation to memory cells in a first area according to a first verification voltage to obtain a first verification result; and
performing an erase operation to the memory cells in the first area, and a strength of the erase operation being determined according to the first verification result.

9. The operating method of claim 8, wherein the strength of the erase operation is controlled by at least one of an erase voltage and an erase time.

10. The operating method of claim 8, wherein when a largest threshold voltage of the memory cells in the first area is greater than or equal to the first verification voltage, the strength of the erase operation is set to a first strength, and
when the largest threshold voltage of the memory cells in the first area is less than the first verification voltage, the strength of the erase operation is set to a second strength less than the first strength.

11. The operating method of claim 8, wherein before the erase operation, a second read operation is performed to at least one selected memory cell according to a second verification voltage to obtain a second verification result, and
a preprogram operation is performed to the at least one selected memory cell coupled to a same word line in the first area, and a strength of the preprogram operation is determined according to the second verification result.

12. The operating method of claim 11, wherein when a largest threshold voltage of the at least one selected memory cell coupled to the same word line in the first area is greater than or equal to the second verification voltage, the strength of the preprogram operation is set to a third strength, and
when the largest threshold voltage of the at least one selected memory cell coupled to the same word line in the first area is less than the second verification voltage, the strength of the preprogram operation is set to a fourth strength greater than the third strength.

13. The operating method of claim 8, wherein after the erase operation, a third read operation is performed to a selected memory cell according to a third verification voltage to obtain a third verification result, and
a soft program operation is performed to the selected memory cell in the first area, and a strength of the soft program operation is determined according to the third verification result.

14. The operating method of claim 13, wherein when a threshold voltage of the selected memory cell is greater than or equal to the third verification voltage, the strength of the soft program operation is set to a fifth strength, and
when the threshold voltage of the selected memory cell is less than the third verification voltage, the strength of the soft program operation is set to a sixth strength greater than the fifth strength.

15. The operating method of claim 8, wherein after the erase operation, a fourth read operation is performed to a programmed memory cell in a second area outside the first area according to a fourth verification voltage to obtain a fourth verification result,
a refresh program operation is performed to the programmed memory cell in the second area, and a strength of the refresh program operation is determined according to the fourth verification result.

16. The operating method of claim 15, wherein when a threshold voltage of the programmed memory cell is greater than or equal to the fourth verification voltage, the strength of the refresh program operation is set to a seventh strength, and
when the threshold voltage of the programmed memory cell in the second area is less than the fourth verification voltage, the refresh program operation is set to an eighth strength greater than the seventh strength.

17. A memory system, configured to control operations of a memory cell, the memory system comprising:
a memory array comprising a memory cell;
a controller coupled to the memory array and configured to:
perform a first read operation to the memory cell according to a first verification voltage to obtain a first verification result;
perform a second read operation to the memory cell according to a second verification voltage less than the first verification voltage to obtain a second verification result; and
perform a program operation to the memory according to the first and second verification results, and a program strength of the program operation being determined according to the second verification result; and
a program circuit coupled to the controller and configured to provide a program signal having a first strength or a second strength greater than the first strength to the memory cell according to the first and second verification results.

18. The memory system of claim 17, wherein the program circuit comprises:
a first switch circuit configured to selectively provide a first program signal having the first strength to the memory cell through a bit line;
a second switch circuit configured to selectively provide a second program signal having the second strength to the memory cell through the bit line; and
a logic circuit coupled to the first and second switches, and configured to control the first and second switches to allow one of the first and second program signals to the memory cell through the bit line according to the first and second verification results.

19. The memory system of claim 18, wherein when the first and second verification results show that the threshold voltage of the memory cell is between the first and second verification voltages, the first switch circuit is controlled by the logic circuit to provide the first program signal having the first strength to the memory cell through the word line, and
when the first and second verification results show that the threshold voltage of the memory cell is less than the second verification voltage, the second switch circuit is controlled by the logic circuit to provide the second program signal having the second strength to the memory cell through the bit line.

20. The memory system of claim 17, wherein the strength of the program operation is controlled by at least one of a program voltage and a program time of the program signal.
